(19) United States
(12) Patent Application Publication
(10) Pub. No.: US 2024/0057463 A1
(43) Pub. Date: Feb. 15, 2024

(54) DEPOSITION DEVICE AND METHOD FOR MANUFACTURING DISPLAY DEVICE USING THE SAME

(71) Applicant: Samsung Display Co., LTD., Yongin-si (KR)

(72) Inventor: Young Min MOON, Yongin-si (KR)

(73) Assignee: Samsung Display Co., LTD., Yongin-si (KR)

(21) Appl. No.: 18/447,404

(22) Filed: Aug. 10, 2023

(30) Foreign Application Priority Data
Aug. 10, 2022 (KR) 10-2022-0100192

(51) Int. Cl. H10K 71/20; H10K 71/10; H01L 33/00; G03F 7/20

(52) U.S. Cl. CPC H10K 71/233; H10K 71/10; H01L 33/005; G03F 7/2002; G03F 7/2043; H10K 59/1201

(57) ABSTRACT

A method for manufacturing a display device according to an embodiment includes forming a first light emitting material layer on a substrate; forming a first photosensitive pattern on the first light emitting material layer; and forming a first emission layer according to a first dry etching process with the first photosensitive pattern as a mask, wherein the forming of a first photosensitive pattern includes irradiating vacuum ultraviolet rays to a photosensitive material layer.

### CROSS-REFERENCE TO RELATED APPLICATION

This application claims priority to and the benefit of Korean Patent Application No. 10-2022-0100192 under 35 U.S.C. § 119, filed in the Korean Intellectual Property Office (KIPO) on Aug. 10, 2022, the entire contents of which are incorporated herein by reference.

### BACKGROUND

### 1. Technical Field

The disclosure relates to a deposition device and a method for manufacturing a display device using the same.

### 2. Description of the Related Art

Display devices include a liquid crystal display (LCD), a plasma display panel (PDP), an organic light emitting diode (OLED) device, a field emission display (FED), and an electrophoretic display device.

In case that the display devices are formed, organic layers may be formed in of pixels areas.

The above information disclosed in this Background section is only for enhancement of understanding of the background of the disclosure, and therefore it may contain information that does not form the prior art that is already known in this country to a person of ordinary skill in the art.

### SUMMARY

The disclosure has been made in an effort to provide a deposition device for manufacturing a wide display device or a high-resolution display device while minimizing damage to an emission layer during a manufacturing process, and a method for manufacturing a display device using the same.

An embodiment of the disclosure provides a deposition device including a first chamber in which a substrate is mounted; a light emitting material layer depositing chamber connected to the first chamber; a vacuum ultraviolet rays irradiating chamber connected to the first chamber; and a strip chamber connected to the first chamber, wherein the first chamber, the light emitting material layer depositing chamber, the vacuum ultraviolet rays irradiating chamber, and the strip chamber are in a vacuous state.

The deposition device may further include a photosensitive resin composition coating chamber connected to the first chamber.

The photosensitive resin composition coating chamber may be in a vacuous state, an atmospheric pressure state, or a low vacuous state.

Light irradiated by the vacuum ultraviolet rays irradiating chamber may have a wavelength of about 160 nm to about 172 nm.

The light irradiated by the vacuum ultraviolet rays irradiating chamber may have energy of about 7.75 eV to about 7.21 eV.

The deposition device may further include a metal material layer forming chamber that forms a metal material layer.

Another embodiment of the disclosure provides a method for manufacturing a display device, the method including forming a first light emitting material layer on a substrate; forming a first photosensitive pattern on the first light emitting material layer; and forming a first emission layer according to a first dry etching process with the first photosensitive pattern as a mask, wherein the forming of a first photosensitive pattern may include irradiating vacuum ultraviolet rays to a photosensitive material layer.

The forming of a first light emitting material layer, the forming of a first photosensitive pattern, and the first dry etching process may be performed in a vacuous state.

The first photosensitive pattern may be etched to have a first-1 thickness to a first-2 thickness in the first dry etching process.

The method may further include forming a second light emitting material layer on the first photosensitive pattern with the first-2 thickness and the substrate; forming a second photosensitive pattern on the second light emitting material layer; and forming a second emission layer according to a second dry etching process with the second photosensitive pattern as a mask.

The second photosensitive pattern may be etched to have a second-1 thickness to a second-2 thickness, and the first photosensitive pattern may be etched to have a first-3 thickness in the second dry etching process.

The method may further include forming a third light emitting material layer on the substrate, the first photosensitive pattern, and the second photosensitive pattern; forming a third photosensitive pattern on the third light emitting material layer; and forming a third emission layer according to a third dry etching process with the third photosensitive pattern as a mask.

The third photosensitive pattern may be etched to have a third-1 thickness to third-2 thickness in the third dry etching process.

The first photosensitive pattern may be etched to have a first-4 thickness, and the second photosensitive pattern may be etched to have a second-3 thickness in the third dry etching process.

Thicknesses are reduced in order of the first-1 thickness, the second-1 thickness, and the third-1 thickness.

The method may further include removing the first photosensitive pattern, the second photosensitive pattern, and the third photosensitive pattern after the third dry etching process.

The removing of the first to third photosensitive patterns may use a developer, vacuum ultraviolet rays, or a dry etching process.

The method may further include forming a metal material layer on the first light emitting material layer.

The first dry etching process may include a metal material layer etching process that provides a first gas, and a light emitting material layer etching process for providing a second gas, and the first gas and the second gas may be different from each other.

The first gas may include a fluorine-based gas, and the second gas includes an oxygen-based gas.

According to the embodiments, the deposition device for manufacturing a wide display device or a high-resolution display device while minimizing damages to an emission layer during a manufacturing process, and the method for manufacturing a display device using the same may be provided.

### BRIEF DESCRIPTION OF THE DRAWINGS

FIG. 1 shows a schematic diagram of a deposition device according to an embodiment.

FIG. 2 to FIG. 12 show schematic cross-sectional views of a method for manufacturing a display device using a deposition device according to an embodiment.

FIG. 13 to FIG. 23 show schematic cross-sectional views of a method for manufacturing a display device using a deposition device according to an embodiment.

FIG. 24 shows a schematic plan view of a region of a display device according to an embodiment.

FIG. 25 shows a schematic cross-sectional view of a region of a display device according to an embodiment.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

Some parts that may be irrelevant to the description will be omitted to clearly describe the disclosure, and the same elements will be designated by the same reference numerals throughout the specification.

The size and thickness of each configuration shown in the drawings are arbitrarily shown for better understanding and ease of description, but the disclosure is not limited thereto. The thicknesses of layers, films, panels, regions, etc., may be enlarged for clarity. The thicknesses of some layers and areas may be exaggerated for convenience of explanation.

Unless explicitly described to the contrary, the word “comprise”, “include”, or “have”, and variations thereof will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. It may also be understood that if one part and another part are “connected,” they may or may not be integral with each other.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

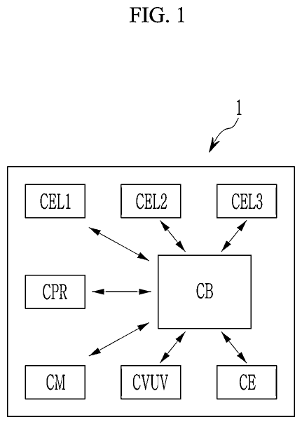

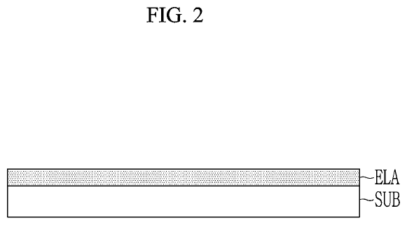

A deposition device and a method for manufacturing a display device using the same according to an embodiment will now be described with reference to FIGS. 1 to 12. FIG. 1 illustrates a schematic diagram of a deposition device according to an embodiment, and FIGS. 2 to 12 illustrate schematic cross-sectional views of a method for manufacturing a display device using a deposition device according to an embodiment.

Referring to FIG. 1, the deposition device 1 according to an embodiment may include a first chamber CB in which a substrate of a display panel is mounted. The first chamber CB may be connected (or extended) to chambers. The first chamber CB may maintain a vacuous state.

The deposition device 1 may include light emitting material layer depositing chambers CEL1, CEL2, and CEL3, a photosensitive resin composition coating chamber CPR, a vacuum ultraviolet rays irradiating chamber CVUV, and a strip chamber CE.

The number of the light emitting material layer depositing chambers CEL1, CEL2, and CEL3 may be set according to types of the light emitting material layers stacked on the substrate. The deposition device 1 may include a first light emitting material layer depositing chamber CELL, a second light emitting material layer depositing chamber CEL2, and a third light emitting material layer depositing chamber CEL3.

The first light emitting material layer depositing chamber CELL may form a first light emitting material layer on the substrate, the second light emitting material layer depositing chamber CEL2 may form a second light emitting material layer on the substrate, and the third light emitting material layer depositing chamber CEL3 may form a third light emitting material layer on the substrate. The first light emitting material layer overlapping an entire surface of the substrate may be formed on the first light emitting material layer depositing chamber CELL The second light emitting material layer overlapping the entire surface of the substrate may be formed on the second light emitting material layer depositing chamber CEL2. The third light emitting material layer overlapping the entire surface of the substrate may be formed on the third light emitting material layer depositing chamber CEL3. The first light emitting material layer may emit light expressing a first color, the second light emitting material layer may emit light expressing a second color, and the third light emitting material layer may emit light expressing a third color. The first color, the second color, and the third color may be different colors from each other, and for example, the first color may be green, the second color may be red, and the third color may be blue.

The respective light emitting material layer depositing chambers CEL1, CEL2, and CEL3 may maintain the vacuous state. The first light emitting material layer depositing chamber CELL, the second light emitting material layer depositing chamber CEL2, and the third light emitting material layer depositing chamber CEL3 may respectively the vacuous state, and may form a light emitting material layer in the vacuous state.

The respective light emitting material layer depositing chambers CEL1, CEL2, and CEL3 may be connected to the first chamber CB. The substrate mounted in the first chamber CB may be moved (e.g., shuttle) between the first chamber CB and the light emitting material layer depositing chambers CELL, CEL2, and CEL3 by an in-and-out system.

A photosensitive resin composition layer may be formed on the substrate in the photosensitive resin composition coating chamber CPR. The photosensitive resin composition layer formed in the photosensitive resin composition coating chamber CPR may overlap the entire surface of the substrate. The photosensitive resin composition coating chamber CPR may form the photosensitive resin composition layer with multiple thicknesses depending on a manufacturing process.

The photosensitive resin composition coating chamber CPR may be connected to the first chamber CB. The substrate mounted in the first chamber CB may be moved between the first chamber CB and the photosensitive resin composition coating chamber CPR by the in-and-out system.

The photosensitive resin composition coating chamber CPR may be in the vacuous state, a low vacuous state, or an atmospheric pressure state.

Vacuum ultraviolet rays may be irradiated or emitted to the substrate in the vacuum ultraviolet rays irradiating chamber CVUV. The vacuum ultraviolet rays may be irradiated or emitted to the photosensitive resin composition layer formed on the substrate. Light irradiated from the vacuum ultraviolet rays irradiating chamber CVUV may have a wavelength of about 160 nm to about 172 nm, and may have an energy of about 7.75 eV to about 7.21 eV.

In case that the vacuum ultraviolet rays are irradiated or emitted to the photosensitive resin composition layer in the vacuum ultraviolet rays irradiating chamber CVUV, the photosensitive resin composition layer may have a specific pattern. A mask may be used to provide a photosensitive pattern with a specific pattern.

The vacuum ultraviolet rays irradiating chamber CVUV may be connected to the first chamber CB. The substrate mounted in the first chamber CB may be moved between the first chamber CB and the vacuum ultraviolet rays irradiating chamber CVUV by the in-and-out system. The vacuum ultraviolet rays irradiating chamber CVUV may irradiate or emit the vacuum ultraviolet rays to the substrate in the vacuous state.

The photosensitive pattern remaining on the substrate may be removed in the strip chamber CE. It may be a chamber for removing a portion of the photosensitive pattern that remains on an emission layer according to the manufacturing process. The strip chamber CE may use a developer, may irradiate or emit the vacuum ultraviolet rays, or may use a dry etching process to remove the photosensitive pattern. In case that the vacuum ultraviolet rays are irradiated or emitted or the dry etching process is used according to an embodiment, the strip chamber CE may provide the vacuous state, and in case that the developer is used to remove the photosensitive pattern, the strip chamber CE may provide the atmospheric pressure state. The vacuum ultraviolet rays provided in the strip chamber CE may be equivalent to the vacuum ultraviolet rays irradiated in the vacuum ultraviolet rays irradiating chamber CVUV.

The strip chamber CE may be connected to the first chamber CB. The substrate mounted in the first chamber CB may be moved between the first chamber CB and the strip chamber CE by the in-and-out system.

The deposition device 1 according to an embodiment may further include a metal material layer forming chamber CM. A metal material layer may be formed on the substrate in the metal material layer forming chamber CM. The metal material layer forming chamber CM may provide the vacuous state, and the metal material layer may be formed on the substrate in the vacuous state. The metal material layer and the light emitting material layer may be formed in a same form, and for example, the metal material layer may overlap the entire surface of the substrate. The metal material layer and the light emitting material layer may be formed to have different thicknesses, and for example, the metal material layer may be thinner than the light emitting material layer.

The metal material layer forming chamber CM may be connected to the first chamber CB. The substrate mounted in the first chamber CB may be moved between the first chamber CB and the metal material layer forming chamber CM by the in-and-out system.

A method for manufacturing a display device by using a deposition device 1 shown in FIG. 1 will now be described with reference to FIGS. 2 to 12.

Referring to FIGS. 1 and 2, the substrate SUB mounted in the first chamber CB may be moved to the first light emitting material layer depositing chamber CELL. As shown in FIG. 2, a first light emitting material layer ELA may be formed on the substrate SUB. The first light emitting material layer ELA may overlap the entire surface of the substrate SUB. The first light emitting material layer ELA may be formed on the substrate SUB in the vacuous state. The substrate SUB may be moved to the first chamber CB.

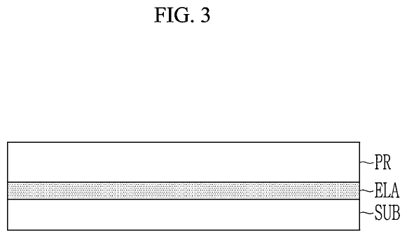

Referring to FIGS. 1 and 3, the substrate SUB mounted in the first chamber CB may be moved to the photosensitive resin composition coating chamber CPR to thus form the photosensitive resin composition layer PR on the first light emitting material layer ELA. As shown in FIG. 3, the photosensitive resin composition layer PR may overlap the entire surfaces of the substrate SUB and the first light emitting material layer ELA. The substrate SUB may be moved into the first chamber CB.

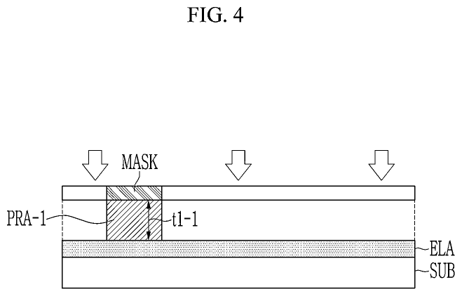

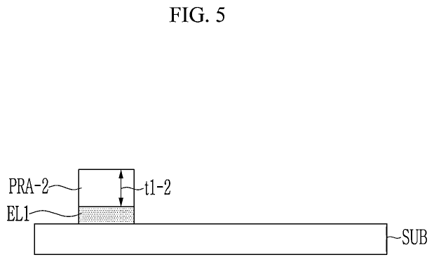

Referring to FIGS. 1 and 4, the substrate SUB mounted in the first chamber CB may be moved to the vacuum ultraviolet rays irradiating chamber CVUV. A mask MASK may be disposed on the substrate SUB in the vacuum ultraviolet rays irradiating chamber CVUV, and the vacuum ultraviolet rays may be irradiated or emitted to the mask MASK to form a first photosensitive pattern PRA-1. A portion that is not blocked by the mask MASK may be removed, and the photosensitive resin composition layer blocked by the mask MASK may form the first photosensitive pattern PRA-1. The first photosensitive pattern PRA-1 may have a first-1 thickness t1-1. The photosensitive resin composition layer PR according to an embodiment may be removed by a process for irradiating vacuum ultraviolet rays, and no additional developing process may be needed. In the manufacturing process omitting the developing process, damage to the light emitting material layer may be minimized A first dry etching process may be performed on the substrate SUB with the first photosensitive pattern PRA-1 as a mask. As shown in FIG. 5, a first emission layer EL1 may be formed on the substrate SUB. A first photosensitive pattern PRA-2 exposed during a process for performing the first dry etching process may be etched to have a first-2 thickness t1-2.

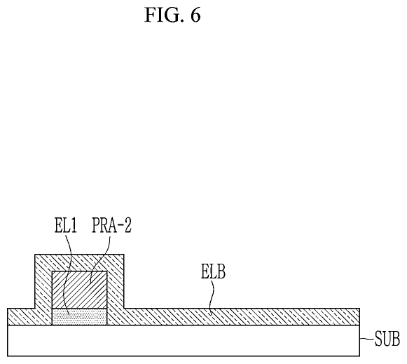

Referring to FIG. 6, a second light emitting material layer ELB overlapping the entire surface of the substrate SUB may be formed on the substrate SUB. The second light emitting material layer ELB may be formed on the substrate SUB in the vacuous state. The substrate SUB may be moved to the first chamber CB.

The substrate SUB mounted in the first chamber CB may be moved to the photosensitive resin composition coating chamber CPR, and the photosensitive resin composition layer may be formed on the second light emitting material layer ELB. As shown and described with reference to FIG. 3, the photosensitive resin composition layer may overlap the entire surfaces of the substrate SUB and the second light emitting material layer ELB.

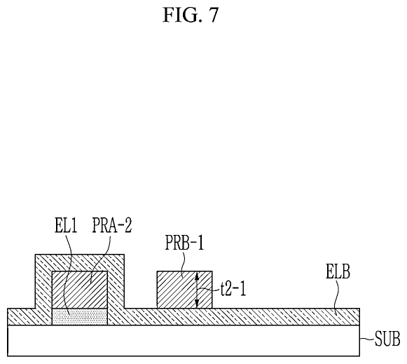

Referring to FIG. 7, the vacuum ultraviolet rays may be irradiated or emitted to the substrate SUB moved into the vacuum ultraviolet rays irradiating chamber CVUV to form a second photosensitive pattern PRB-1. A portion of the photosensitive resin composition layer that is not blocked by the mask may be removed, and a portion of the photosensitive resin composition layer blocked by the mask may form the second photosensitive pattern PRB-1. The second photosensitive pattern PRB-1 may have a second-1 thickness t2-1. The photosensitive resin composition layer according to an embodiment may be removed by the process for irradiating vacuum ultraviolet rays, and no additional developing process may be needed.

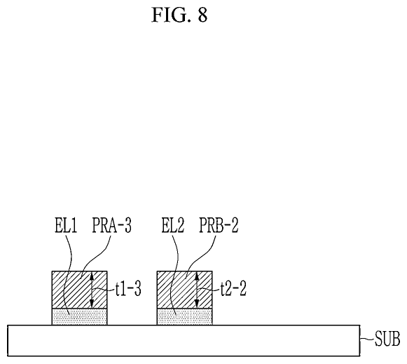

A secondary dry etching process may be performed with the second photosensitive pattern PRB-1 as a mask. Hence, as shown in FIG. 8, a second emission layer EL2 may be formed on the substrate SUB. A second photosensitive pattern PRB-2 exposed during a process for performing the secondary dry etching process may have a second-2 thickness t2-2. A first photosensitive pattern PRA-3 exposed during the process for performing the secondary dry etching process may have a first-3 thickness t1-3.

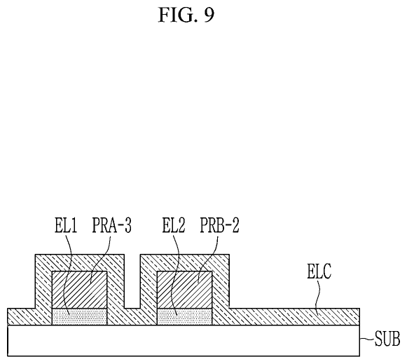

Referring to FIG. 9, a third light emitting material layer ELC overlapping the entire surface of the substrate SUB may be formed on the substrate SUB. The third light emitting material layer ELC may be formed on the substrate SUB in the vacuous state. The substrate SUB may be moved to the first chamber CB.

The substrate SUB mounted in the first chamber CB may be moved to the photosensitive resin composition coating chamber CPR to form the photosensitive resin composition layer on the third light emitting material layer ELC. As shown and described with reference to FIG. 3, the photosensitive resin composition layer may overlap the entire surfaces of the substrate SUB and the third light emitting material layer ELC.

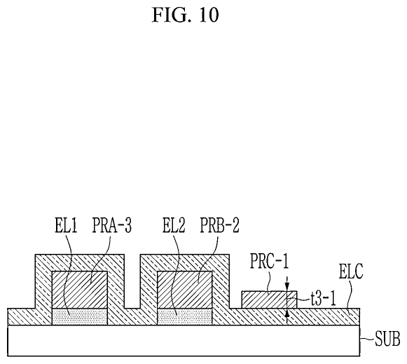

Referring to FIG. 10, the vacuum ultraviolet rays may be irradiated or emitted to the substrate SUB moved in the vacuum ultraviolet rays irradiating chamber CVUV to form a third photosensitive pattern PRC-1. A portion of the photosensitive resin composition layer that is not blocked by the mask may be removed, and a portion of the photosensitive resin composition layer blocked by the mask may form the third photosensitive pattern PRC-1. The third photosensitive pattern PRC-1 may have a third-1 thickness t3-1. The photosensitive resin composition layer according to an embodiment may be removed by the process for irradiating vacuum ultraviolet rays, and no additional developing process may be needed.

A third dry etching process may be performed with the third photosensitive pattern PRC-1 as a mask.

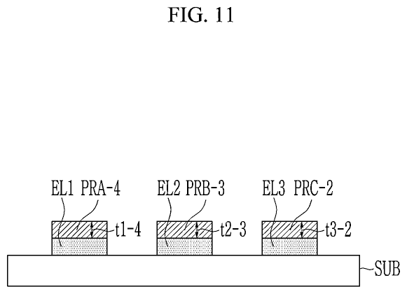

As shown in FIG. 11, a third emission layer EL3 may be formed on the substrate SUB. A third photosensitive pattern PRC-2 exposed during the process for performing a third dry etching process may have a third-2 thickness t3-2. A first photosensitive pattern PRA-4 exposed during the process for performing the third dry etching process may have a first-4 thickness t1-4. A second photosensitive pattern PRB-3 exposed during the process for performing the third dry etching process may have a second-3 thickness t2-3.

The first photosensitive pattern may be etched to have the first-1 thickness t1-1, the first-2 thickness t1-2, the first-3 thickness t1-3, and the first-4 thickness t1-4 as the etching process progresses. The thicknesses may be reduced in order of the first-1 thickness t1-1, the first-2 thickness t1-2, the first-3 thickness t1-3, and the first-4 thickness t1-4. The second photosensitive pattern may be etched to have the second-1 thickness t2-1, the second-2 thickness t2-2, and the second-3 thickness t2-3 as the etching process progresses. The thicknesses may be reduced in order of the second-1 thickness t2-1, the second-2 thickness t2-2, and the second-3 thickness t2-3. The third photosensitive pattern may be etched to have the third-1 thickness t3-1 and the third-2 thickness t3-2 as the etching process progresses. The thicknesses may be reduced in order of the third-1 thickness t3-1 and the third-2 thickness t3-2. Further, the thicknesses may be reduced in order of the first-1 thickness t1-1, the second-1 thickness t2-1, and the third-1 thickness t3-1.

The above-described method for manufacturing a display device may be performed in the vacuous chamber.

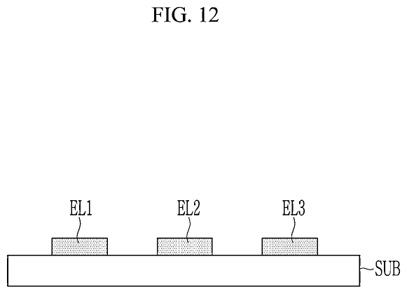

By removing the photosensitive pattern from the substrate SUB moved to the strip chamber CE, the first emission layer EL1, the second emission layer EL2, and the third emission layer EL3 disposed on the substrate SUB may be provided, as shown in FIG. 12.

The strip chamber CE may remove the photosensitive pattern by using a developer, irradiating the vacuum ultraviolet rays, or using the dry etching process.

According to the method for manufacturing a display device according to an embodiment, most of the processes for forming emission layers Ell, EL2, and EL3 may be performed in the vacuum, and damage to the emission layer may be minimized By patterning the photosensitive resin composition layer according to the vacuum ultraviolet rays irradiate process, no additional developing process may be needed, thereby minimizing damage to the emission layer. By removing the photosensitive pattern by a one-time strip process, damage to the emission layer may be minimized. The process is simpler and easier than the case of providing the emission layer by using an individual fine metal mask (FMM), and thus a high-resolution and wide display device may be readily provided.

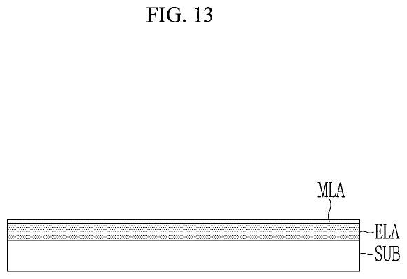

A method for manufacturing a display device according to an embodiment will now be described with reference to FIGS. 13 to 23. FIGS. 13 to 23 illustrate schematic cross-sectional views of a method for manufacturing a display device using a deposition device according to an embodiment. Descriptions of the same constituent elements as the above-described constituent elements may be omitted.

The substrate SUB mounted in the first chamber CB may be moved into the first light emitting material layer depositing chamber CELL. As shown in FIG. 13, a first light emitting material layer ELA may be formed on the substrate SUB in the first light emitting material layer depositing chamber CEL1. The first light emitting material layer ELA may overlap the entire surface of the substrate SUB. A first metal material layer MLA may be formed on the substrate SUB moved into the metal material layer forming chamber CM.

The first metal material layer MLA may include Yb, Ag, and Mg. The thickness of the first metal material layer MLA may be less than the thickness of the first light emitting material layer ELA, and for example, it may be about 20 angstroms to about 150 angstroms.

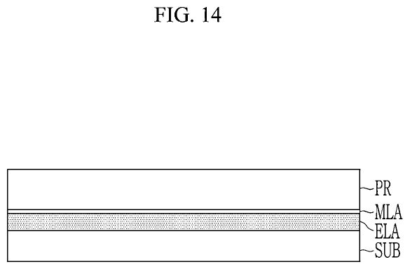

The substrate SUB mounted in the first chamber CB may be moved to the photosensitive resin composition coating chamber CPR. As shown in FIG. 14, a photosensitive resin composition layer PR may be formed on the first metal material layer MLA.

The photosensitive resin composition layer PR may overlap the entire surfaces of the substrate SUB, the first light emitting material layer ELA, and the first metal material layer MLA. The substrate SUB may be moved into the first chamber CB. The substrate SUB mounted in the first chamber CB may be moved to the vacuum ultraviolet rays irradiating chamber CVUV.

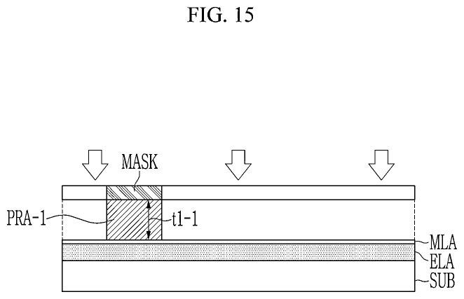

As shown in FIG. 15, the vacuum ultraviolet rays may be irradiated or emitted to the mask MASK disposed on the substrate SUB in the vacuum ultraviolet rays irradiating chamber CVUV to form a first photosensitive pattern PRA-1. The photosensitive resin composition layer that is not blocked by the mask MASK may be removed, and the photosensitive resin composition layer blocked by the mask MASK may form the first photosensitive pattern PRA-1. The first photosensitive pattern PRA-1 may have a first-1 thickness t1-1.

The photosensitive resin composition layer PR that is not blocked by the mask MASK may be removed by the process for irradiating vacuum ultraviolet rays, and no additional developing process may be needed.

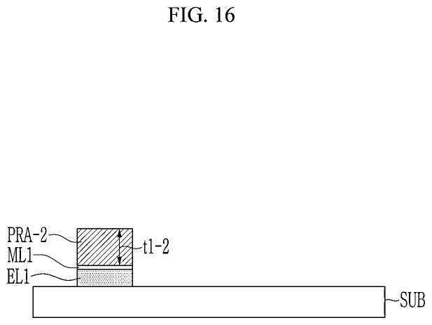

A first dry etching process may be performed on the entire surface of the substrate SUB with the first photosensitive pattern PRA-1 as a mask. As shown in FIG. 16, a first emission layer EL1 and a first metal layer ML1 may be formed on the substrate SUB.

The first dry etching process may include a metal material layer dry etching process for forming the first metal layer ML1 and a light emitting material layer dry etching process for forming the first emission layer ELL The metal material layer dry etching process and the light emitting material layer dry etching process may be sequentially performed. The metal material layer dry etching process may use a first gas, and the light emitting material layer dry etching process may use a second gas. The first gas may be a fluorine-based gas, and the second gas may be an oxygen-based gas.

The first photosensitive pattern PRA-2 exposed during the process for performing a first dry etching process may be etched to have a first-2 thickness t1-2.

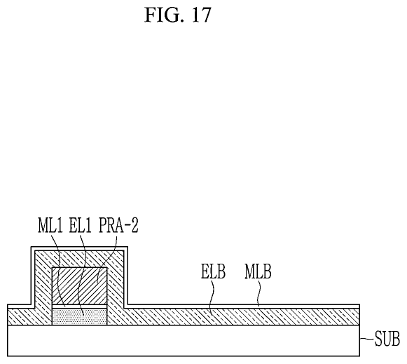

Referring to FIG. 17, a second light emitting material layer ELB may be formed on the substrate SUB. The second light emitting material layer ELB may be formed to overlap the entire surface of the substrate SUB in the vacuous state. The substrate SUB may be moved to the metal material layer forming chamber CM, and a second metal material layer MLB positioned on the second light emitting material layer ELB may be formed.

The substrate SUB may be moved to the photosensitive resin composition coating chamber CPR to form a photosensitive resin composition layer overlapping the entire surface of the substrate SUB on the second metal material layer MLB. The photosensitive resin composition layer may correspond to what is shown and described with reference to FIG. 14.

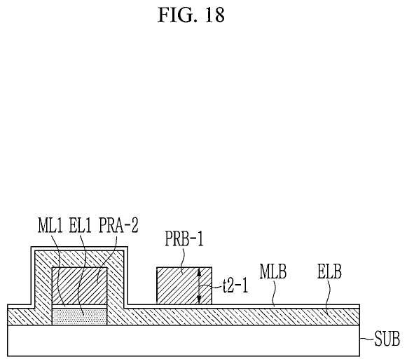

As shown in FIG. 18, the vacuum ultraviolet rays may be irradiated or emitted to the substrate SUB moved into the vacuum ultraviolet rays irradiating chamber CVUV to form a second photosensitive pattern PRB-1. A portion of the photosensitive resin composition layer that is not blocked by the mask may be removed, and a portion of the photosensitive resin composition layer blocked by the mask may form the second photosensitive pattern PRB-1. The second photosensitive pattern PRB-1 may have a second-1 thickness t2-1. The photosensitive resin composition layer according to an embodiment may be removed by the process for irradiating vacuum ultraviolet rays, and no additional developing process may be needed.

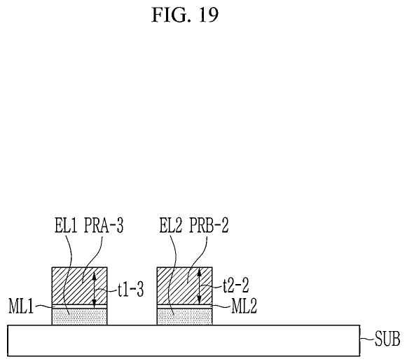

The secondary dry etching process may be performed with the second photosensitive pattern PRB-1 as a mask. As shown in FIG. 19, a second emission layer EL2 and a second metal layer ML2 may be formed on the substrate SUB. The second photosensitive pattern PRB-2 exposed during the process for performing the secondary dry etching process may have a second-2 thickness t2-2. The first photosensitive pattern PRA-3 exposed during the process for performing the second dry etching process may have a first-3 thickness t1-3.

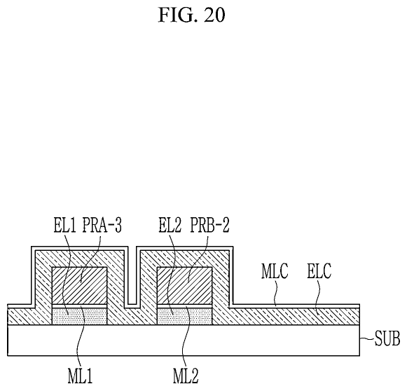

Referring to FIG. 20, a third light emitting material layer ELC overlapping the entire surface of the substrate SUB may be formed on the substrate SUB. The third light emitting material layer ELC may be formed on the substrate SUB in the vacuous state. The substrate SUB may be moved to the metal material layer forming chamber CM to form a third metal material layer MLC positioned on the third light emitting material layer ELC.

The substrate SUB may be moved to the photosensitive resin composition coating chamber CPR to form a photosensitive resin composition layer on the third metal material layer MLC. As shown and described with reference to FIG. 14, the photosensitive resin composition layer may overlap the entire surfaces of the substrate SUB, the third light emitting material layer ELC, and the third metal material layer MLC.

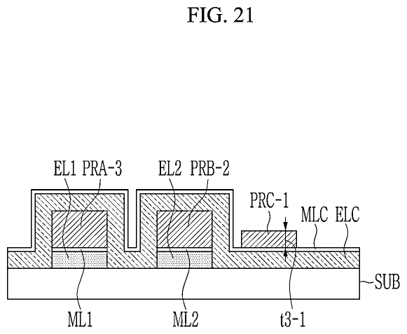

Referring to FIG. 21, the vacuum ultraviolet rays may be irradiated or emitted to the substrate SUB moved in the vacuum ultraviolet rays irradiating chamber CVUV to form a third photosensitive pattern PRC-1. A portion of the photosensitive resin composition layer that is not blocked by the mask may be removed, and a portion of the photosensitive resin composition layer blocked by the mask may form the third photosensitive pattern PRC-1. The third photosensitive pattern PRC-1 may have a third-1 thickness t3-1. The photosensitive resin composition layer according to an embodiment may be removed by the process for irradiating vacuum ultraviolet rays, and no additional developing process may be needed. A dry etching process may be performed with the third photosensitive pattern PRC-1 as a mask.

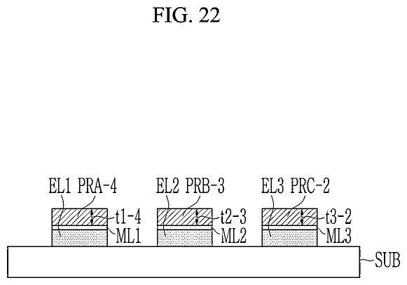

As shown in FIG. 22, a third emission layer EL3 and a third metal layer ML3 may be formed on the substrate SUB. The third photosensitive pattern PRC-2 exposed during the process for performing a third dry etching process may have a third-2 thickness t3-2. The first photosensitive pattern PRA-4 exposed during the process for performing the third dry etching process may have a first-4 thickness t1-4. The second photosensitive pattern PRB-3 exposed during the process for performing the third dry etching process may have a second-3 thickness t2-3.

The first photosensitive pattern may be etched to have the first-1 thickness t1-1, the first-2 thickness t1-2, the first-3 thickness t1-3, and the first-4 thickness t1-4 as the etching process progresses. The thicknesses may be reduced in order of the first-1 thickness t1-1, the first-2 thickness t1-2, the first-3 thickness t1-3, and the first-4 thickness t1-4. The second photosensitive pattern may be etched to have the second-1 thickness t2-1, the second-2 thickness t2-2, and the second-3 thickness t2-3 as the etching process progresses. The thicknesses may be reduced in order of the second-1 thickness t2-1, the second-2 thickness t2-2, and the second-3 thickness t2-3. The third photosensitive pattern may be etched to have the third-1 thickness t3-1 and the third-2 thickness t3-2 as the etching process progresses. The thicknesses may be reduced in order of the third-1 thickness t3-1 and the third-2 thickness t3-2. Further, the thicknesses may be reduced in order of the first-1 thickness t1-1, the second-1 thickness t2-1, and the third-1 thickness t3-1.

The above-described method for manufacturing a display device may be performed in the vacuous chamber.

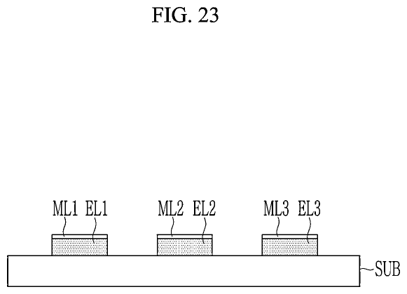

By removing the photosensitive pattern from the substrate SUB moved to the strip chamber CE, the first emission layer EL1 and the first metal layer ML1, the second emission layer EL2 and the second metal layer ML2, and the third emission layer EL3 and the third metal layer ML3 disposed on the substrate SUB may be provided, as shown in FIG. 23.

According to the manufacturing method described with reference to FIGS. 13 to 23, metal layers disposed on the respective emission layers may be further included. As the metal layer may protect the emission layer during the manufacturing process, the emission layer with improved reliability and the display device including the same may be provided.

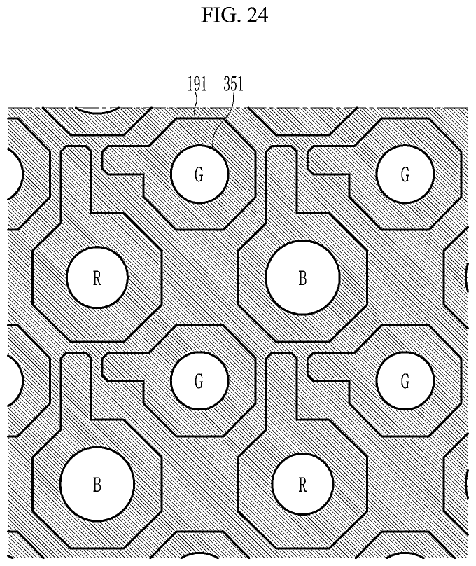

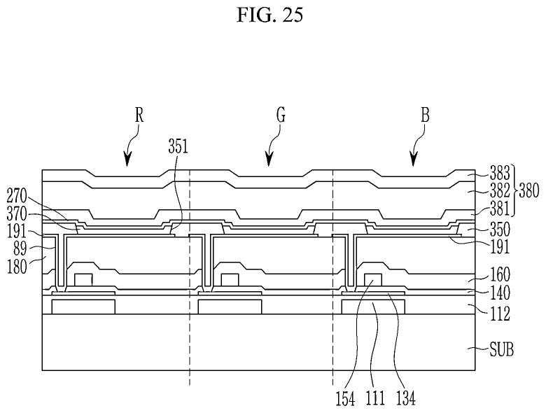

A display device generated according to the above-noted manufacturing process will now be described with reference to FIGS. 24 and 25. FIG. 24 illustrates a schematic top plan view of a display device according to an embodiment, and FIG. 25 illustrates a schematic cross-sectional view of a display device according to an embodiment. An example of a display device including an emission layer manufactured by using the deposition device 1 according to an embodiment will now be described with reference to FIGS. 24 and 25.

The display device according to an embodiment includes pixels, which are basic units for displaying images. The pixels may include pixels for displaying different colors, and FIG. 24 illustrates that the pixels include a red pixel R, a green pixel G, and a blue pixel B.

The red pixel R and the blue pixel B may be alternately arranged in a horizontal direction, the blue pixel B and the green pixel G may be alternately arranged in a diagonal direction, and the red pixel R and the green pixel G may be alternately arranged in another diagonal direction. However, disposition of the pixels is not limited thereto.

Referring to FIG. 25, the display device according to an embodiment may include a substrate SUB on which pixels R, G, and B are positioned. The substrate SUB may include an insulating material such as glass or plastic, and may have flexibility.

A first conductive layer including a conductive pattern 111, signal lines and voltage lines may be positioned on the substrate SUB. The first conductive layer may include a conductive metal or a semiconductor material having a conductive characteristic that corresponds to the conductive metal.

A buffer layer 112 that is an insulating layer may be positioned on the first conductive layer, and active patterns 134 may be positioned on the buffer layer 112. The active pattern 134 may include a semiconductor material including an oxide semiconductor such as amorphous silicon, polysilicon, or IGZO.

A first insulating layer 140 may be positioned on the active pattern 134, and a second conductive layer including a gate electrode 154 may be positioned on the first insulating layer 140. The active pattern 134 and the gate electrode 154 may configure a thin-film transistor.

At least one of the first conductive layer and the second conductive layer may include at least one of copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), and their alloys.

A second insulating layer 160 may be positioned on the second conductive layer, and a third insulating layer 180 may be positioned on the second insulating layer 160.

At least one of the buffer layer 112, the second insulating layer 160, and the third insulating layer 180 may include an inorganic insulating material and/or an organic insulating material such as a silicon nitride (SiNx), a silicon oxide (SiOx), or a silicon oxynitride (SiON). The second insulating layer 160 may be omitted.

A third conductive layer including pixels electrodes 191 may be positioned on the third insulating layer 180. The pixel electrode 191 may be electrically connected to a conductive region of the active pattern 134 through openings 89 of the first insulating layer 140, the second insulating layer 160, and the third insulating layer 180.

The third conductive layer may include a semi-transmitting conductive material or a reflective conductive material.

A fourth insulating layer 350 may be positioned on the third conductive layer. The fourth insulating layer 350 may have an opening 351 positioned in the pixel electrode 191 of the pixels R, G, and B. The fourth insulating layer 350 according to an embodiment may include an inorganic insulating material such as a silicon nitride (SiNx), a silicon oxide (SiOx), or a silicon oxynitride (SiON).

Emission layers 370 may be positioned on the respective pixel electrodes 191. The emission layer 370 may include a portion positioned in the opening 351 of the fourth insulating layer 350. The emission layer 370 may be formed through the above-noted deposition device 1. The emission layer 370 may include an organic light emitting material or an inorganic light emitting material, and may include a host material and a dopant material.

A common electrode 270 may be positioned on the emission layer 370. The common electrode 270 may be formed on pixels R, G, and B. The common electrode 270 may include a conductive transparent material.

The respective pixel electrodes 191, the emission layer 370, and the common electrode 270 may configure a light emitting diode (LED) that is a light-emitting device, and at least one of the pixel electrode 191 and the common electrode 270 may become a cathode and the other may become an anode.

Referring to FIGS. 24 and 25, the region in which the opening 351 of the fourth insulating layer 350 is positioned on the pixel electrode 191 may become light emitting regions of the respective pixels R, G, and B.

An encapsulation layer 380 including insulating layers 381, 382, and 383 may be positioned on the common electrode 270. The insulating layer 381 and the insulating layer 382 may include an inorganic insulating material, and the insulating layer 382 positioned between the insulating layer 381 and the insulating layer 382 may include an organic insulating material.

Although not shown in FIG. 25, as shown in FIG. 23, an individual metal layer positioned on the emission layer may be included. In case that the metal layer and the common electrode 270 includes a same material and the metal layer is formed by an individual process, a layer may be formed.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition device comprising:
a first chamber in which a substrate is mounted;
a light emitting material layer depositing chamber connected to the first chamber;
a vacuum ultraviolet rays irradiating chamber connected to the first chamber; and
a strip chamber connected to the first chamber,
wherein the first chamber, the light emitting material layer depositing chamber, the vacuum ultraviolet rays irradiating chamber, and the strip chamber are in a vacuous state.

2. The deposition device of claim 1, wherein
the deposition device further includes a photosensitive resin composition coating chamber connected to the first chamber.

3. The deposition device of claim 2, wherein
the photosensitive resin composition coating chamber is in a vacuous state, an atmospheric pressure state, or a low vacuous state.

4. The deposition device of claim 1, wherein
light irradiated by the vacuum ultraviolet rays irradiating chamber has a wavelength of about 160 nm to about 172 nm.

5. The deposition device of claim 4, wherein
the light irradiated by the vacuum ultraviolet rays irradiating chamber has energy of about 7.75 eV to about 7.21 eV.

6. The deposition device of claim 1, wherein
the deposition device further includes a metal material layer forming chamber that forms a metal material layer.

7. A method for manufacturing a display device, the method comprising:
forming a first light emitting material layer on a substrate;
forming a first photosensitive pattern on the first light emitting material layer; and
forming a first emission layer according to a first dry etching process with the first photosensitive pattern as a mask,
wherein the forming of a first photosensitive pattern includes irradiating vacuum ultraviolet rays to a photosensitive material layer.

8. The method of claim 7, wherein
the forming of a first light emitting material layer, the forming of a first photosensitive pattern, and the first dry etching process are performed in a vacuous state.

9. The method of claim 7, wherein
the first photosensitive pattern is etched to have a first-1 thickness to a first-2 thickness in the first dry etching process.

10. The method of claim 9, further comprising:
forming a second light emitting material layer on the first photosensitive pattern with the first-2 thickness and the substrate;
forming a second photosensitive pattern on the second light emitting material layer; and
forming a second emission layer according to a second dry etching process with the second photosensitive pattern as a mask.

11. The method of claim 10, wherein
the second photosensitive pattern is etched to have a second-1 thickness to a second-2 thickness, and the first photosensitive pattern is etched to have a first-3 thickness in the second dry etching process.

12. The method of claim 11, further comprising:
forming a third light emitting material layer on the substrate, the first photosensitive pattern, and the second photosensitive pattern;
forming a third photosensitive pattern on the third light emitting material layer; and
forming a third emission layer according to a third dry etching process with the third photosensitive pattern as a mask.

13. The method of claim 12, wherein
the third photosensitive pattern is etched to have a third-1 thickness to third-2 thickness in the third dry etching process.

14. The method of claim 13, wherein
the first photosensitive pattern is etched to have a first-4 thickness, and the second photosensitive pattern is etched to have a second-3 thickness in the third dry etching process.

15. The method of claim 14, wherein
thicknesses are reduced in order of the first-1 thickness, the second-1 thickness, and the third-1 thickness.

16. The method of claim 12, further comprising
removing the first photosensitive pattern, the second photosensitive pattern, and the third photosensitive pattern after the third dry etching process.

17. The method of claim 16, wherein
the removing of the first to third photosensitive patterns uses a developer, vacuum ultraviolet rays, or a dry etching process.

18. The method of claim 7, further comprising:
forming a metal material layer on the first light emitting material layer.

19. The method of claim 18, wherein
the first dry etching process includes:
a metal material layer etching process that provides a first gas; and
a light emitting material layer etching process that provides a second gas; and
the first gas and the second gas are different from each other.

20. The method of claim 19, wherein
the first gas includes a fluorine-based gas, and
the second gas includes an oxygen-based gas.
